(19) United States
(12) Patent Application Publication
(10) Pub. No.: US 2025/0366322 A1
(43) Pub. Date: Nov. 27, 2025

(54) DISPLAY PANEL AND PREPARATION METHOD THEREOF

(71) Applicant: Shenzhen China Star Optoelectronics Semiconductor Display Technology Co., Ltd., Shenzhen (CN)

(72) Inventors: Zhijun WAN, Shenzhen (CN); Jinchuan LI, Shenzhen (CN); Weiran CAO, Shenzhen (CN)

(73) Assignee: Shenzhen China Star Optoelectronics Semiconductor Display Technology Co., Ltd., Shenzhen (CN)

(21) Appl. No.: 18/679,189

(22) Filed: May 30, 2024

(30) Foreign Application Priority Data
May 21, 2024 (CN) 202410628711.7

(51) Int. Cl. H10K 59/131; H10K 59/12; H10K 59/122; H10K 102/00

(52) U.S. Cl. CPC H10K 59/131; H10K 59/1201; H10K 59/122; H10K 2102/351

(57) ABSTRACT

A display panel and a preparation method thereof are provided. The display panel provides a channel through a support member at a junction between a buffer area and a cathode overlap area on a light-emitting device layer, so that a material of a cathode can be introduced to the cathode overlap area through the channel and overlapped with a wiring exposed by a first opening. The electron function layer adopts an evaporation process, and the cathode adopts a sputtering process or an evaporation process with a smaller evaporation angle and forms the electron function layer and the cathode with a same mask.

### CROSS-REFERENCE TO RELATED APPLICATION

This application claims priority to Chinese Patent Application No. 202410628711.7, filed on May 21, 2024, which is hereby incorporated by reference in its entirety.

### TECHNICAL FIELD

The present application relates to the field of display technology, and more particularly, to a display panel and a preparation method thereof.

### BACKGROUND

An OLED panel may be prepared using an ink jet printing (IJP) process and an evaporation (EV)/sputtering (SPT) process. Due to limited development of an ink of an electron transport material (ETM) and an electron injection material (EIM), an IJP OLED panel is currently prepared by depositing OLED function layers such as a hole injection layer (HIL), a hole transport layer (HTL), and a light-emitting layer (EML) in the IJP process, and depositing OLED function layers such as an electron transport layer (ETL), an electron injection layer (EIL), and a cathode in the EV/SPT process.

The cathode of the OLED panel needs to be overlapped with the metal wiring on the driving substrate, so that the circuit controls the OLED to emit lights. Therefore, the film-forming area of the cathode needs to be greater than the film-forming areas of the ETL and the EIL, so that the cathode is directly overlapped with the metal wiring. The EV/SPT process achieves differences in sizes of the film-forming areas based on changing the openings of the masks, and the opening of mask for the film-forming of the cathode needs to be greater than the opening of the opening of the mask for the film-forming of the ETL&EIL. That is, different masks are required to form the OLED function layers which results in an increase in manufacturing costs.

### SUMMARY

An embodiment of the present application provides a display panel and a preparation method thereof, to reduce the manufacturing cost of the display panel.

An embodiment of the present application provides a display panel including a display area and a non-display area on at least one side of the display area; wherein the non-display area comprises a buffer area, and a cathode overlap area on a side of the buffer area away from the display area; wherein the display panel comprises: a thin film transistor structure layer including a wiring, and an insulating layer covering the wiring; wherein a first opening is provided on the insulating layer in the cathode overlap area, and the first opening exposes the wiring; a light-emitting device layer disposed on the thin film transistor structure layer; wherein the light-emitting device layer comprises an electron function layer, and a cathode disposed on a side of the electron function layer away from the thin film transistor structure layer; and a support member disposed on the insulating layer and at junction between the buffer area and the cathode overlap area; wherein in the buffer area, the light-emitting device layer is provided with at least one channel extending through the support member to the cathode overlap area, and the first opening is disposed in an extension direction of the channel; and in the non-display area of an orthographic projection of the display panel, a boundary of the cathode exceeds a boundary of the electron function layer, the electron function layer covers at least the display area and the buffer area, and the cathode covers the display area and the buffer area and is connected to the wiring at the first opening through the channel.

In an embodiment, the light-emitting device layer comprises a flat layer covering the insulating layer and a pixel definition layer covering the flat layer, and the electron function layer covers the pixel definition layer; and wherein a bottom surface height of the channel is lower than a surface of the pixel definition layer away from the thin film transistor structure layer and in the display area, with a reference surface made to a surface of the insulating layer close to the flat layer, and a bottom surface of the channel is higher than or equal to the reference surface.

In an embodiment, the channel includes at least one first hollow and a plurality of second hollows, one of the at least one first hollow communicates with at least one of the plurality of second hollows, the at least one first hollow and the plurality of second hollows extend through the flat layer and the pixel definition layer, the at least one first hollow is disposed in the buffer area, and the plurality of second hollows extends through the support member; and in the orthographic projection of the display panel, an extension direction of the plurality of second hollows intersects an extension direction of the wiring.

In an embodiment, at least one first opening is provided, and in the orthographic projection of the display panel, one of the at least one first opening is at least correspondingly provided in the extension direction of one of the plurality of second hollows.

In an embodiment, one first opening is provided, and in the orthographic projection of the display panel, the one first opening is arranged to extend along the extension direction of the wiring, and the one first opening is correspondingly arranged along the extension direction of the plurality of second hollows.

In an embodiment, in the orthographic projection of the display panel, the at least one first opening is provided at intervals along the extension direction of the wiring, and one of the at least one first opening is correspondingly provided in the extension direction of one of the plurality of second hollows.

In an embodiment, a plurality of support members is provided; in the orthographic projection of the display panel, the plurality of support members is arranged at intervals along the extension direction of the wiring; and each of the plurality of support members is disposed between two adjacent first openings in an extension direction parallel to the extension direction of the plurality of second hollows; and the cathode includes a plurality of overlapping portions in the cathode overlap area, each of the plurality of overlapping portions is provided in each of the at least one first opening and is connected to the wiring, and the plurality of overlapping portions is arranged at intervals along the extension direction of the wiring.

In an embodiment, in the orthographic projection of the display panel, each of the plurality of support members support member is disposed on side areas of each of the at least one first opening along the extension direction of the plurality of second hollows.

In an embodiment, a width of each of the plurality of second hollow ranges from 10 microns to 500 microns.

In an embodiment, at least one of the flat layer and the pixel definition layer is disposed in a same layer as at least a portion of the support member and has same material as the portion of the support member.

In an embodiment, the support member comprises a first portion, a second portion, and a third portion stacked on the insulating layer in sequence; the first portion is provided in a same layer as the flat layer and has same material as the flat layer; and the second portion is provided in a same layer as the pixel definition layer and has same material as the pixel definition layer.

In an embodiment, a width of the support member is greater than or equal to 10 microns.

In an embodiment, a thickness of the support member is greater than or equal to 4 microns.

In an embodiment, the electron function layer is connected to a portion of the wiring at the first opening through the channel, and the cathode covers the electron function layer in the first opening and is connected to an exposed portion of the wiring.

In an embodiment, the electron function layer comprises at least one of an electron transport layer and an electron injection layer; and the light-emitting device layer further comprises an anode, a light-emitting layer, and a hole function layer; wherein the anode is disposed on the flat layer, the pixel definition layer is provided with a second opening, and the second opening exposes the anode; wherein the hole function layer and the light-emitting layer are disposed on the anode in sequence and in the second opening, and the electron function layer is disposed on the light-emitting layer.

Accordingly, a preparation method of display panel, wherein the display panel comprises a display area and a non-display area located on at least one side of the display area; the non-display area comprises a buffer area and a cathode overlap area on a side of the buffer area away from the display area; and the preparation method of display panel comprises: forming a support member on a thin film transistor structure layer including a wiring and an insulating layer covering the wiring; wherein a first opening is provided on the insulating layer in the cathode overlap area, the first opening exposes the wiring, the support member is provided on the insulating layer at a junction between the buffer area and the cathode overlap area, at least one channel is provided on the support member, the channel communicates with the buffer area and the cathode overlap area, and the first opening is disposed in an extension direction of the channel; providing one mask on the support member, wherein an opening area of the mask is disposed corresponding to the display area and the buffer area, and a shielding area of the mask is disposed corresponding to the cathode overlap area; and forming an electron function layer and a cathode on the thin film transistor structure layer in sequence with the mask, a boundary of the cathode exceeds a boundary of the electron function layer, the electron function layer covers at least the display area and the buffer area, and the cathode covers the display area and the buffer area and is connected to the wiring at the first opening through the channel.

A display panel according to an embodiment of the present application provides a channel through a support member at a junction of a buffer area and a cathode overlap area on a light-emitting device layer, so that a material of the cathode can be introduced to the cathode overlap area through the channel and overlapped with a wiring exposed by a first opening.

That is, the electron function layer adopts an evaporation process, and the cathode adopts a sputtering process or an evaporation process with a smaller evaporation angle and forms the electron function layer and the cathode with a same mask. By providing the channel, the material of the cathode and the electron function layer can extend through the channel to the cathode overlap area. Further, since the cathode is evaporated at a small evaporation angle or adopts a sputtering process, a range of film-forming of the cathode is greater than a range of film-forming of the electron function layer. As such, the cathode can be connected with the wiring to realize emission of the light-emitting device layer, thereby reducing the manufacturing cost of the display panel.

### BRIEF DESCRIPTION OF THE DRAWINGS

FIG. 1 is a front view of a display panel according to an embodiment of the present application;

FIG. 2A is an enlarged view of part Q in FIG. 1;

FIG. 2B is an enlarged view of part O in FIG. 1;

FIG. 3 is a schematic cross-sectional view taken along a line CC of FIG. 2A;

FIG. 4 is a schematic cross-sectional view taken along a DD line of FIG. 2A;

FIG. 5 is a partial front view of a display panel according to another embodiment of the present application;

FIG. 6 is a schematic diagram of curves of a cathode and an electron function layer corresponding to different film thicknesses at different distances;

FIG. 7 is a partial front view of a display panel according to yet another embodiment of the present application;

FIG. 8 is a schematic cross-sectional view taken along a SS line of FIG. 7;

FIG. 9 is a schematic sectional view of a display panel according to yet another embodiment of the present application;

FIG. 10 is a schematic diagram of step B1 of a preparation method of display panel according to an embodiment of the present application;

FIG. 11 is a schematic diagram of step B2 of a preparation method of display panel according to an embodiment of the present application; and

FIG. 12 is a schematic diagram of step B3 of a preparation method of display panel according to an embodiment of the present application.

### DETAILED DESCRIPTION OF THE EMBODIMENTS

In the following, the technical solutions in the embodiments of the present application will be clearly and completely described in connection with the accompanying drawings in the embodiments of the present application. It should be understood that the described embodiments are merely a part of the embodiments of the present application, rather than all the embodiments. Based on the embodiments in the present application, all other embodiments obtained by a person skilled in the art without involving any inventive effort are in the scope of the present application. Furthermore, it should be understood that the specific embodiments described herein are for purposes of illustration and explanation only and are not intended to limit the application. In the present application, without stating to the contrary, the use of positional terms such as “on” and “under” refer to the positon on and under the device in actual use or operation, of which reference is specifically made to the direction in the drawings; and the terms “in” and “out” are for the outline of the device. The terms “first”, “second”, “third” and the like are used merely as labels and do not impose numerical requirements or order.

An example of the present application provides a display panel and a preparation method thereof, which are described in detail below. It should be noted that the order in which the following examples are described is not intended to limit the preferred order of the examples.

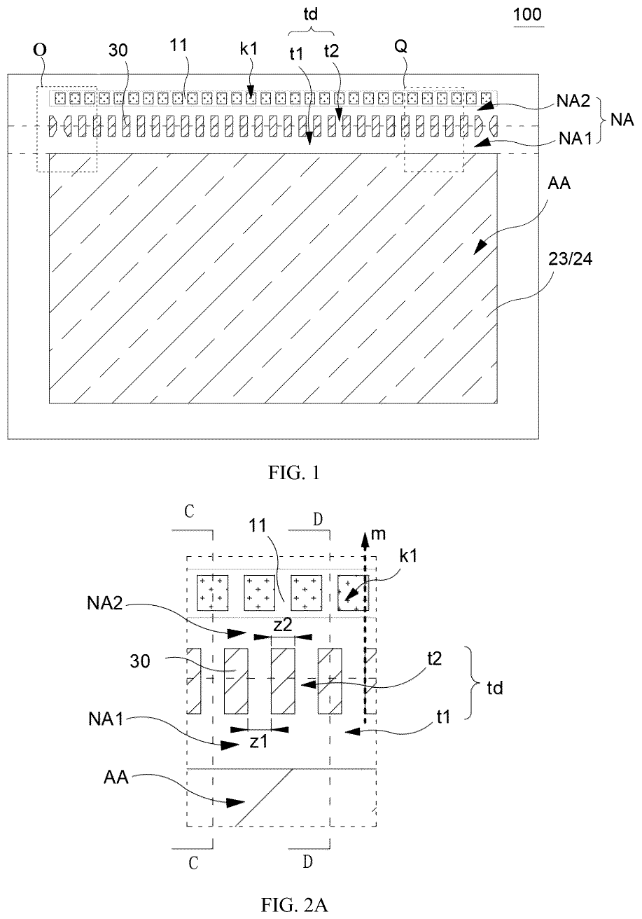

Referring to FIG. 1 to FIG. 4, an embodiment of the present application provides a display panel 100 including a display area AA, and a non-display area NA on at least one side of the display area AA. The non-display area NA includes a buffer area NA1, and a cathode overlap area NA2 on a side of the buffer area NA1 away from the display area AA.

The display panel 100 includes a thin film transistor structure layer 10, a light-emitting device layer 20, and a support member 30.

The thin film transistor structure layer 10 includes a wiring 11, and an insulating layer 12 covering the wiring 11. In the cathode overlap area NA2, a first opening k1 is provided on the insulating layer 12, and the first opening k1 exposes the wiring 11.

The light-emitting device layer 20 is disposed on the thin film transistor structure layer 10. The light-emitting device layer 20 includes an electron function layer 21, and a cathode 22 disposed on a side of the electron function layer 21 away from the thin film transistor structure layer 10.

The support member 30 is disposed on the insulating layer 12 at a junction of the buffer area NA1 and the cathode overlap area NA2.

In the buffer area NA1, the light-emitting device layer 20 is provided with at least one channel td. The channel td extends through the support member 30 to the cathode overlap area NA2, and the first opening k1 is disposed in the extending direction of the channel td.

In the non-display area NA of the front view of the display panel 100, the boundary of the cathode 22 exceeds the boundary of the electron function layer 21, which covers at least the display area AA and the buffer area NA1, the cathode 22 covers the display area AA and the buffer area NA1 and extends along the channel td into the cathode overlap area NA2, and the cathode 22 extends into the first opening k1 to connect to the wiring 11. That is, the cathode 22 extends through the channel td to connect to the wiring 11 at the first opening k1.

The display panel 100 according to an embodiment of the present application provides the channel td through the support member 30 is provided at the junction of the buffer area NA1 and the cathode overlap area NA2 on the light-emitting device layer 20, so that the material of the cathode 22 is introduced to the cathode overlap area NA2 through the channel td and is overlapped the wiring 11 exposed by the first opening k1.

That is, the electron function layer 21 is prepared by an evaporation process, and the cathode 22 is prepared by a sputtering process or an evaporation process with a smaller evaporation angle, and the electron function layer 21 and the cathode 22 are formed by using the same mask. By arranging the channel td, the material of the cathode 22 and the electron function layer 21 can extend through the channel td to the cathode overlap area NA2. Since the cathode 22 is prepared by a sputtering process or an evaporation process with a smaller evaporation angle, the range of the film-forming of the cathode 22 is greater than the range of the film-forming of the electron function layer. As such, the cathode can be overlapped with the wiring to achieve emission of lights of the light-emitting device layer, thereby reducing the manufacturing cost of the display panel.

In an embodiment, the non-display area NA is provided on one side of the display area AA, and the wiring 11 is provided on only one side of the display area AA. In some embodiments, the non-display area NA may be provided around the display area AA, and the wiring 11 forms a closed-loop structure around the periphery of the display area AA. In some embodiments, the non-display areas NA are provided on two or three adjacent sides of the display area AA, and the wiring 11 is provided on the periphery of the display area AA in a folded line shape.

In an embodiment, the electron function layer 21 is extended through the channel td to connect to the wiring 11 at the first opening k1. The cathode 22 is covered on the electron function layer 21 in the first opening k1 and is connected to the exposed portion of the wiring 11. Such an arrangement may reduce the width of the non-display area NA.

In an embodiment, it is also possible that the electron function layer 21 does not overlap the wiring 11 in the first opening k1, thereby improving the stability of the overlapping of the wiring 11 with the cathode 22.

In an embodiment, the thin film transistor structure layer 10 may be at least one of a top gate type thin film transistor, a bottom gate type thin film transistor, a double gate type thin film transistor, and a vertical type thin film transistor. This embodiment is described by way of example, but not by way of limitation, in a top gate type thin film transistor.

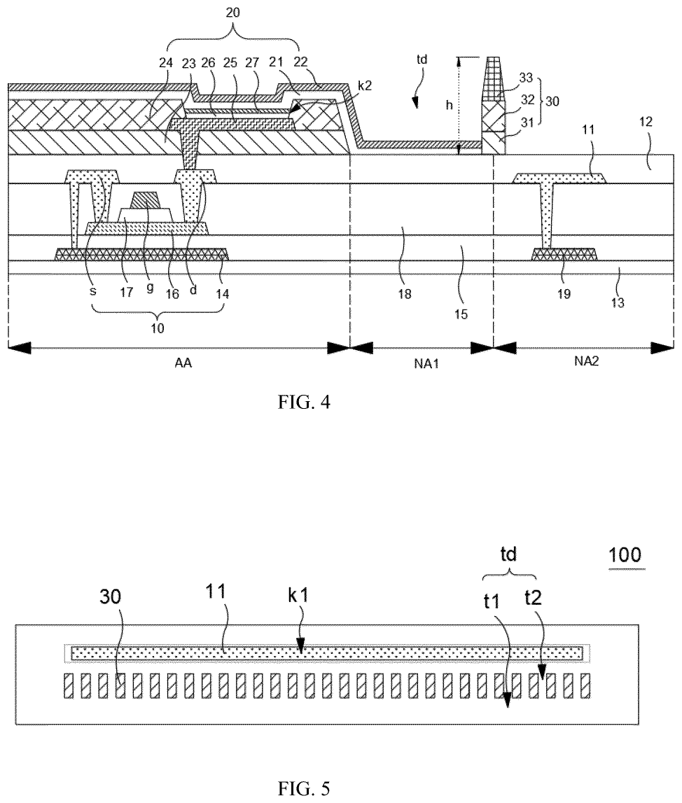

Referring to FIG. 3 to FIG. 4, in an embodiment, the thin film transistor structure layer 10 includes a substrate 13, a light-shielding layer 14, a buffer layer 15, an active layer 16, a gate insulating layer 17, a gate g, an interlayer dielectric layer 18, a source s, and a drain d, which are stacked in sequence. The wiring 11 are disposed on the interlayer dielectric layer 18 in the same layer as the source s. The insulating layer 12 also covers the source s, the drain d, and the interlayer dielectric layer 18.

In an embodiment, the thin film transistor structure layer 10 further includes a signal access line 19 arranged in the same layer with the light-shielding layer 14, the signal access line 19 is spaced apart from the light-shielding layer 14, and the signal access line 19 is connected to the wiring 11 through a via. The signal access line 19 is arranged to access the cathode signal.

In an embodiment, the light-emitting device layer 20 includes a flat layer 23 covering the insulating layer 12, and a pixel definition layer 24 covering the flat layer 23. The electron function layer 21 covers the pixel definition layer 24.

The light-emitting device layer 20 also includes an anode 25, a hole function layer 26, and a light-emitting layer 27. The anode 25 is provided on the flat layer 23. The pixel definition layer 24 is provided with a second opening k2, which exposes the anode 25. The hole function layer 26 and the light-emitting layer 27 are sequentially provided on the anode 25 and in the second opening k2. The electron function layer 21 is provided on the light-emitting layer 27. The anode 25 is connected to the drain d of the thin film transistor through a via.

In an embodiment, the electron function layer 21 includes at least one of an electron transport layer and an electron injection layer. The hole function layer 26 includes at least one of a hole transport layer and a hole injection layer. In the present embodiment, the electron function layer 21 includes an electron transport layer and an electron injection layer stacked on the light-emitting layer 27 in sequence. The hole function layer 26 includes the hole injection layer and the hole transport layer stacked on the anode 25 in sequence.

In an embodiment, the support member 30 is used to support the mask. That is, when the preparation of the electron function layer 21 and the cathode 22 is performed, the same mask is overlapped on the support member 30. The display area AA and the buffer area NA1 are exposed to the openings of the mask, and the cathode overlap area NA2 is shielded by the mask, so that the cathode material and the electron function layer material pass through the channel td into the cathode overlap area NA2 by the diffusion phenomenon of the material in the manufacturing process. The portion of the material entering the cathode overlap area NA2 is referred as a shadow.

In an embodiment, the bottom surface of the channel td is lower the surface of the pixel definition layer 24 away from the thin film transistor structure layer 10 and in the display area AA, which is based on the reference surface referring to the insulating layer 12 close to the flat layer 23. The bottom surface of the channel td is higher than or equal to the reference surface.

For example, in the buffer area NA1, a hollow is provided on the flat layer 23 to expose the insulating layer 12, and the pixel definition layer 24 covers the hollow to define a recess having a lower potential than the display area AA. The channel td is defined by the recess, and the channel td extends through the support member 30 to introduce the material to the cathode overlap area NA2.

For another example, in the buffer area NA1, a hollow exposing the flat layer 23 is formed in the pixel definition layer 24, and the hollow forms a recess with the top surface of the flat layer 23, and the channel td defined by the recess extends through the support member 30 to introduce the material to the cathode overlap area NA2.

For another example, in an embodiment, the channel td includes at least one first hollow t1 and a plurality of second hollows t2. The first hollow t1 is communicated with at least one second hollow t2. The first hollow t1 and the second hollow port t2 both extend through the flat layer 23 and the pixel definition layer 24. The first hollow t1 is located in the buffer area NA1, and the second hollow t2 extends through the support member 30. That is, the bottom surface of the channel td is equal to the reference surface.

In the orthographic projection of the display panel 100, the extension direction m of the second hollow t2 intersects with the extension direction of the wiring 11.

The channel td is deeper to penetrate through the flat layer 23 and the pixel definition layer 24, so that the second hollow t2 is less blocked at the front, and more materials can pass through the second hollow t2. As such, the overlap area and the overlap thickness of the cathode 22 and the wiring 11 are increased, and the stability of overlapping the wiring 11 with the cathode 22 is improved.

It should be understood that the less the obstacle of the second hollow t2 at the front, the more material extends through the second hollow t2. In addition, the deeper the second hollow t2, the less the obstacle of the first opening k1 at the front, and the more material enters the first opening k1, thereby improving the stability of overlapping with the wiring 11.

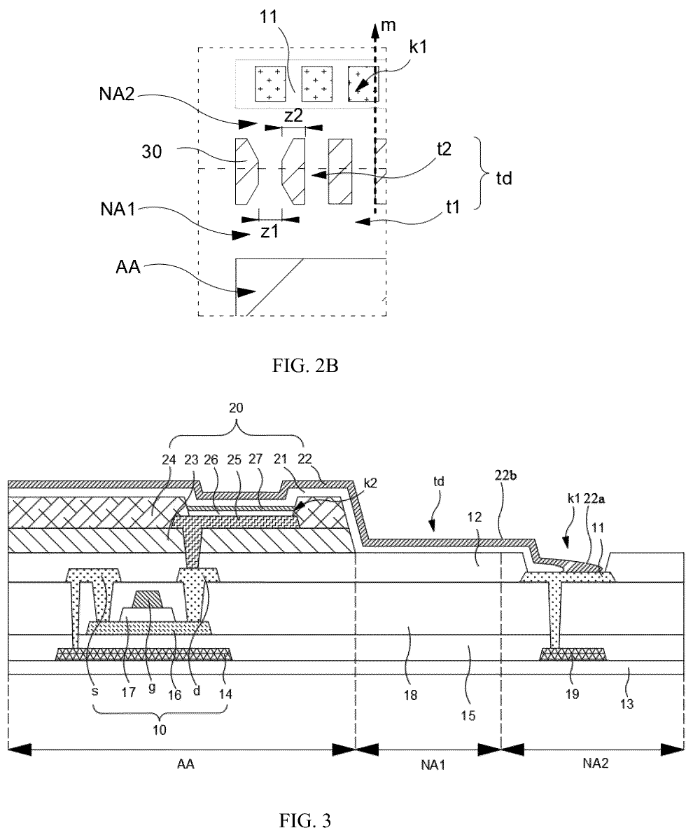

Referring to FIG. 1 to FIG. 2B, the channel td includes one first hollow t1 and a plurality of second hollow t2. The one first hollow t1 exposes a portion of the buffer area NA1 located in the insulating layer 12, the first hollow t1 extends along the extension direction of the wiring 11, and the length of the first hollow t1 is equal to or greater than the length of the wiring 11. As such, all the second hollows t2 are communicated with the first hollow t1, and no obstacle is provided at the front of the second hollow port t2 to block the passage of the material of the cathode, thereby improving the penetration rate of the material through the second hollow t2.

In an embodiment, in the orthographic projection of the display panel 100, the extension direction m of the second hollow t2 is perpendicular to the extension direction of the wiring 11, so that the distance of the material entering the first opening k1 is the same, and the cathode 22 is insured to overlap with the wiring 11.

In an embodiment, in the orthographic projection of the display panel 100, a plurality of channels td is arranged at intervals along the extension direction of the wiring 11, and the channel td is arranged to extend along the direction perpendicular to the extension direction of the wiring 11.

In an embodiment, at least one first opening k1 is provided. In the orthographic projection of the display panel 100, the at least one first opening k1 is disposed corresponding to the extension direction m of at least one second hollow t2.

In an embodiment, referring to FIG. 2A, in the orthographic projection of the display panel 100, a plurality of first openings k1 are provided at intervals along the extension direction of the wiring 11, and one first opening k1 is disposed corresponding to the extension direction m of one second hollow t2.

The plurality of first openings k1 are arranged at intervals so that the insulating layer 12 is covered on the wiring 11 at intervals, thereby reducing the risk of stripping the wiring 11.

In an embodiment, referring to FIG. 5, in an embodiment of the present application, one first opening k1 is provided. In the orthographic projection of the display panel 100, the first opening k1 is provided to extend along the extension direction of the wiring 11, and one first opening k1 is provided corresponding to in the extension direction m of the plurality of second hollows t2. The exposed area of the wirings 11 is increased by the first opening k1 in an elongated shape, so that the cathode 22 can overlap the wiring 11 more and increase the overlapping area.

In an embodiment, in the orthographic projection of the display panel 100, a plurality of first openings k1 is arranged at intervals along the extension direction of the wiring 11, and one first opening k1 is correspondingly arranged in the extension direction m of at least two second hollows t2. In this arrangement, the overlapping area of the cathode 22 and the wiring 11 can be considered, and the risk of easy stripping of the wiring 11 can be reduced.

In an embodiment, a plurality of support members 30 is provided. The plurality of support members 30 is arranged at intervals along the extension direction of the wiring 11 in the orthographic projection of the display panel 100. In the extension direction m parallel to the second hollow t2, the support member 30 is positioned between adjacent first openings k1.

The cathode 22 includes a plurality of overlapping portions 22a in the cathode overlapping area NA2. The overlapping portion 22a is provided in the first opening k1 and connected to the wiring 11, and the plurality of overlapping portions 22a is arranged at intervals along the extension direction of the wiring 11.

The plurality of overlapping portions 22a is provided at intervals and covers the side wall of the first opening k1, thereby improving the overlapping area of the overlapping portions 22a and the film layer, and further improving the stability of the attachment. On the other hand, the overlapping portions 22a are provided at intervals, so that the stress release performance of the cathode 22 in the cathode overlap area NA2 is improved, and the bending of the display panel 100 is facilitated.

In an embodiment, in the orthographic projection of the display panel 100, the support member 30 is disposed at both sides of the first opening k1 along the extension direction m of the second hollow t2.

It should be understood that the material passes through the second hollow t2 at a random angle, so that the width of the first opening k1 can be appropriately enlarged to increase the overlapping area of the cathode 22 with the wiring 11.

In an embodiment, in the orthographic projection of the display panel 100, along the extension direction m of the second hollow t2, the support member 30 is positioned between the boundaries of adjacent first openings k1.

In an embodiment, the thickness h of the support member 30 is greater than or equal to 4 microns, such as may be 4 microns, 5 microns, 6 microns, 7 microns, 8 microns, 9 microns, 10 microns, 11 microns, 12 microns, 13 microns, 14 microns, 15 microns, 16 microns, 17 microns, 18 microns, 19 microns, 20 microns, 21 microns, 22 microns, 23 microns, 24 microns, 25 microns, 26 microns, 27 microns, 28 microns, 29 microns, 30 microns, 35 microns, 40 microns, 45 microns, or 50 microns, etc.

It should be understood that the greater the thickness h of the support member 30, the greater the distance of the mask from the bottom surface of the channel td, the greater the range of the material diffusing into the cathode overlap area NA2, and the higher the success rate and stability of the overlapping of the cathode 22 with the wiring 11.

In an embodiment, the width z1 of the second hollow t2 ranges from 10 microns to 500 microns, such as may be 10 microns, 20 microns, 30 microns, 40 microns, 50 microns, 60 microns, 70 microns, 80 microns, 90 microns, 100 microns, 150 microns, 200 microns, 250 microns, 300 microns, 350 microns, 400 microns, 450 microns, or 500 microns.

It should be understood that the smaller the width z1 of the second hollow t2, the smaller the overlapping area of the wiring 11 with the cathode 22, and the stronger the strength of the support member 30 to support the mask. The larger the width z1 of the second hollow t2, the larger the overlapping area of the wiring 11 with the cathode 22, the weaker the strength of the support member 30 to support the mask, and the easier the opening edge of the mask to deform. Therefore, the selection of the width z1 of the second hollow t2 needs to satisfy the overlapping area of the wiring 11 with the cathode 22 and the strength requirement to support the mask.

In an embodiment, as shown in FIG. 2B, the width z1 of the at least one second hollow t2 is increased from the middle to both ends to provide more overlapping areas for the cathode 22 with the wirings 11.

The cathode 22 covers the bottom surface of the second hollowed t2, and a clamping portion 22b is formed in the second hollow t2. Combined with FIG. 2B, the clamping portion 22b has a small width in the middle and a large width at both ends for cooperating the width z1 of the second hollow t2 increased from the middle to both ends. This increases the connection area between the overlapping portion 22a and the clamping portion, limits the moving of the cathode 22, and reduces the risk of peeling the overlapping portion 22a of the cathode 22.

In an embodiment, the width z2 of the support member 30 is greater than or equal to 10 microns, such as may be 10 microns, 20 microns, 30 microns, 40 microns, 50 microns, 60 microns, 70 microns, 80 microns, 90 microns, 100 microns, 150 microns, 200 microns, 250 microns, 300 microns, 350 microns, or 400 microns, and the like.

In an embodiment, the width of the support member 30 is also less than or equal to 400 microns.

It should be understood that the smaller the width z2 of the support member 30, the larger the overlapping area of the wiring 11 with the cathode 22, the weaker the strength of the support member 30 to support the mask, and the easier the opening edge of the mask to deform. The larger the width z2 of the support member 30, the smaller the overlapping area of the wiring 11 with the cathode 22, and the stronger the strength of the support member 30 to support the mask. Therefore, the selection of the width z2 of the support member 30 needs to satisfy the overlapping area of the wiring 11 with the cathode 22 and the strength requirement to support the mask.

In an embodiment, at least one of the flat layer 23 and the pixel definition layer 24 is disposed in the same layer and has the same material as at least a portion of the support member 30. For example, the support member 30 may be formed using the same mask as the flat layer 23 or the pixel definition layer 24. For another example, a portion of the support member 30 is formed using the same mask as the flat layer 23, and another portion of the support member 30 is formed using the same mask as the pixel definition layer 24.

In an embodiment, the support member 30 may also be prepared with other film layers than the flat layer 23 and the pixel definition layer 24 using the same mask. In an embodiment, a portion of the support member 30 is prepared using the same mask as the flat layer 23 or the pixel definition layer 24, and another portion of the support member 30 is prepared using the same mask as the other film layers.

In an embodiment, the support member 30 comprises a first portion 31, a second portion 32 and a third portion 33 stacked in sequence on the insulating layer 12, and the first portion 31 is arranged in the same layer as the flat layer 23 and has the same material as the flat layer 23. The second portion 32 is arranged in the same layer and has the same material as the pixel definition layer 24. The third portion 33 is arranged in the same layer as the spacer and has the same material as the spacer. Such an arrangement may simplify the process.

It should be understood that the electron function layer 21 of the display panel 100 of the embodiments of the present application may be prepared by an evaporation process, and the cathode 22 may be prepared by an evaporation process or a sputtering process. When the electron function layer 21 and the cathode 22 are prepared by the evaporation process, the prepared cathode 22 has a smaller evaporation angle smaller than the electron function layer 21. When the electron function layer 21 can be prepared by an evaporation process, and the cathode 22 can be prepared by a sputtering process, the electron function layer 21 can be prepared by a conventional process regardless of the angle.

When the electron function layer 21 and the cathode 22 are prepared by the evaporation process, the evaporation angle for preparing the cathode 22 is θ. In the area of the channel td, the distance from the first opening k1 to the flat layer 23 and the pixel definition layer 24 in the display area AA is greater than or equal to the thickness of the support member 30 by h/tan θ, to ensure that the flat layer 23 and the pixel definition layer 24 block material from passing through the channel td. In the present application, the electron function layer 21 may be prepared by the evaporation process, and the cathode 22 may be prepared by the sputtering process.

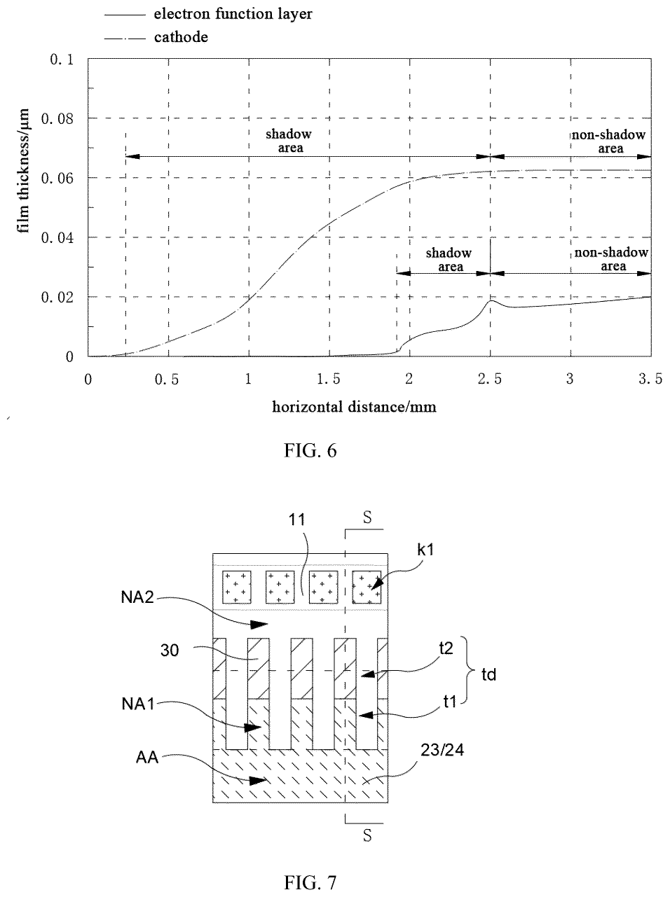

According to the difference between the evaporation process and the sputtering process, the material of the particles sputters at random in the sputtering process, and the material of the particles are limited by the deposition angle in the evaporation process. Therefore, when the same mask is used for deposition, the shadow area of the sputtering process is larger than the shadow area of the evaporation process, that is, the film coverage area of the cathode 22 is larger than the film coverage area of the electron function layer 21 with the same mask for preparing, as shown in FIG. 6.

Since the electron function layer 21 and the cathode 22 use the same mask, only one film-forming chamber can be provided on the production line to prepare the electron function layer 21 and the cathode 22, thereby reducing the preparation cost.

In still another embodiment, referring to FIGS. 7 and 8, compared to the above-described embodiment, a plurality of channels td is provided and is arranged at intervals along the extension direction of the wiring 11. The flat layer 23 and the pixel definition layer 24 extend to the buffer area NA1 and are connected to the support member 30. The channel td extends through the flat layer 23 and the pixel definition layer 24.

The first portion 31 of the support member 30 is integrally formed with the flat layer 23, and the second portion 32 is integrally formed with the pixel definition layer 24 to improve the stability of the support member 30 to the insulating layer 12.

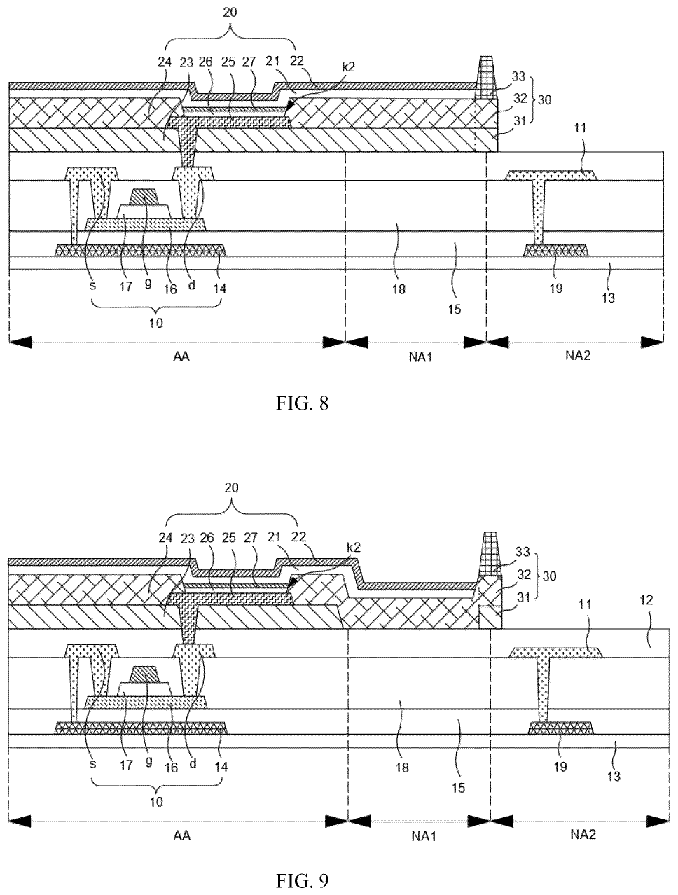

In an embodiment, as shown in FIG. 9, the flat layer 23 may not extend into the buffer area NA1, the pixel definition layer 24 extends into the buffer area NA1 and is connected to the support member 30, and the second portion 32 of the support member 30 is integrally formed with the pixel definition layer 24.

Accordingly, an embodiment of the present application further provides a preparation method of display panel, and the display panel includes a display area and a non-display area on at least one side of the display area. The non-display area includes a buffer area, and a cathode overlap area located on a side of the buffer area away from the display area. The preparation method of display panel includes the following steps.

A support member is formed on a thin film transistor structure layer including a wiring and an insulating layer covering the wiring. A first opening is provided on the insulating layer in the cathode overlap area, and the first opening exposes the wiring. The support member is provided on the insulating layer at a junction between the buffer area and the cathode overlap area. At least one channel is provided on the support member, the channel communicates with the buffer area and the cathode overlap area, and the first opening is disposed in an extension direction of the channel.

A mask is provided on the support member, an opening area of the mask is disposed corresponding to the display area and the buffer area, and a shielding area of the mask is disposed corresponding to the cathode overlap area.

An electron function layer and a cathode are formed on the thin film transistor structure layer in sequence with the same mask, the boundary of the cathode exceeds the boundary of the electron function layer, the electron function layer covers at least the display area and the buffer area, and the cathode covers the display area and the buffer area and is connected to the wiring at the first opening through the channel.

The following describes the preparation method of display panel of the examples of the present application.

It should be understood that the preparation method of display panel of the embodiments of the present application is used to prepare the display panel 100 described in any one of the above embodiments.

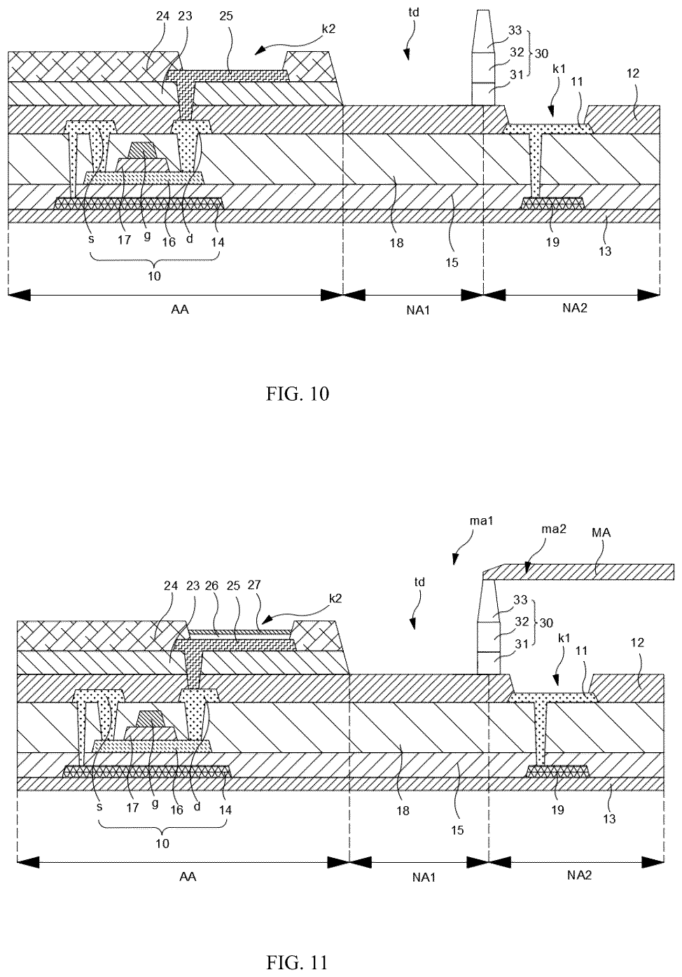

Referring to FIG. 10, in step B1, a support member 30 is formed on the thin film transistor structure layer 10. The thin film transistor structure layer 10 includes a wiring 11, and an insulating layer 12 covering the wiring 11. In the cathode overlap area NA2, a first opening k1 is provided on the insulating layer 12, and the first opening k1 exposes the wiring 11. The support member 30 is disposed on the insulating layer 12 at the junction of the buffer area NA1 and the cathode overlap area NA2. The support member 30 is provided with at least one channel td which communicates the buffer area NA1 and the cathode overlap area NA2, and the first opening k1 is disposed in the extension direction of the channel td.

Herein, before the support member 30 is formed on the thin film transistor structure layer 10, a flat layer 23, an anode 25, and a pixel definition layer 24 are sequentially formed on the thin film transistor structure layer 10.

In an embodiment, the support member 30 includes a first portion 31, a second portion 32, and a third portion 33 stacked sequentially on the insulating layer 12. The first portion 31 and the flat layer 23 are formed using the same mask. The second portion 32 and the pixel definition layer 24 are formed using the same mask. The third portion 33 and the spacer are formed using the same mask. Such an arrangement may simplify the process.

This then proceeds to step B2.

Referring to FIG. 11, in step B2, a mask MA is provided on the support member 30, the opening area ma1 of the mask MA corresponds to the display area AA and the buffer area NA1, and the shielding area ma2 of the mask MA corresponds to the cathode overlap area NA2.

Herein, the mask MA is overlapped on the support member 30.

Before step B2, a hole function layer 26 and a light-emitting layer 27 are sequentially formed on the pixel definition layer 24.

This then proceeds to step B3.

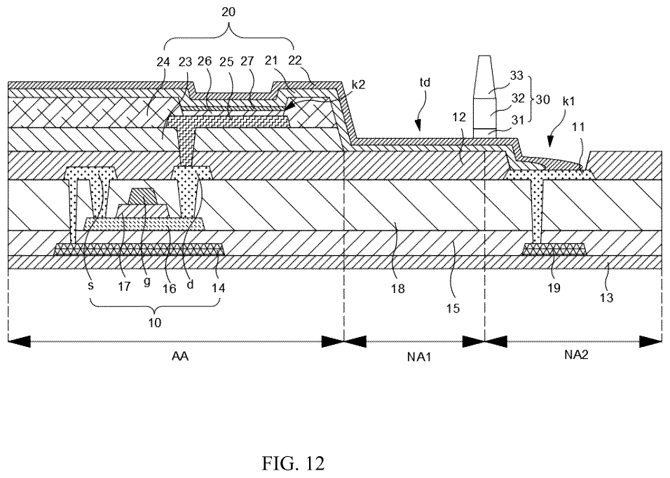

Referring to FIG. 12, in step B3, the electron function layer 21 and the cathode 22 are sequentially formed on the thin film transistor structure layer 10 with the same mask MA, and the boundary of the cathode 21 exceeds the boundary of the electron function layer 22. The electron function layer 21 covers at least the display area AA and the buffer area NA1, and the cathode 22 covers the display area AA and the buffer area NA1 and is connected to the wiring 11 at the first opening k1 through the channel td.

According to the preparation method of the present embodiment, the electron function layer 21 may be prepared by an evaporation process, and the cathode 22 may be prepared by an evaporation process or a sputtering process. When the electron function layer 21 and the cathode 22 are prepared by the evaporation process, the prepared cathode 22 has a smaller evaporation angle smaller than the electron function layer 21. When the electron function layer 21 can be prepared by an evaporation process, and the cathode 22 can be prepared by a sputtering process, the electron function layer 21 can be prepared by a conventional process regardless of the angle.

When the electron function layer 21 and the cathode 22 are prepared by the evaporation process, the evaporation angle for preparing the cathode 22 is θ. In the area of the channel td, the distance from the first opening k1 to the flat layer 23 and the pixel definition layer 24 in the display area AA is greater than or equal to the thickness of the support member 30 by h/tan θ, to ensure that the flat layer 23 and the pixel definition layer 24 block material from passing through the channel td. In the present application, the electron function layer 21 may be prepared by the evaporation process, and the cathode 22 may be prepared by the sputtering process.

According to the difference between the evaporation process and the sputtering process, the material of the particles sputters at random in the sputtering process, and the material of the particles are limited by the deposition angle in the evaporation process. Therefore, when the same mask MA is used for deposition, the shadow area of the sputtering process is larger than the shadow area of the evaporation process, that is, the film coverage area of the cathode 22 is larger than the film coverage area of the electron function layer 21 with the same mask MA for preparing.

Since the electron function layer 21 and the cathode 22 use the same mask MA, only one film-forming chamber can be provided on the production line to prepare the electron function layer 21 and the cathode 22, thereby reducing the preparation cost.

A display panel according to the embodiments of the present application provides a channel through a support member at the junction of the buffer area and the cathode overlap area on the light-emitting device layer, so that a material of the cathode can be introduced to the cathode overlap area through the channel and overlapped with the wiring exposed by the first opening.

The electron function layer is prepared by an evaporation process, and the cathode is prepared by a sputtering process or an evaporation process with a smaller evaporation angle, and the electron function layer and the cathode are formed by using the same mask. By arranging the channel, the material of the cathode and the electron function layer can extend through the channel to the cathode overlap area. Since the cathode is prepared by a sputtering process or an evaporation process with a smaller evaporation angle, the range of the film-forming of the cathode is greater than the range of the film-forming of the electron function layer. As such, the cathode can be overlapped with the wiring to achieve emission of lights of the light-emitting device layer, thereby reducing the manufacturing cost of the display panel.

The present application is described in detail with reference to a display panel and a preparation method thereof, and the principles and embodiments of the present application are described with reference to specific examples. The description of the above examples is merely provided to help understand the method and the core idea of the present application. At the same time, variations will occur to those skilled in the art in both the detailed description and the scope of application in accordance with the teachings of the present application. In view of the foregoing, the present description should not be construed as limiting the application.

1. A display panel, comprising a display area and a non-display area on at least one side of the display area; wherein the non-display area comprises a buffer area, and a cathode overlap area on a side of the buffer area away from the display area; wherein the display panel comprises:
a thin film transistor structure layer including a wiring, and an insulating layer covering the wiring; wherein a first opening is provided on the insulating layer in the cathode overlap area, and the first opening exposes the wiring;
a light-emitting device layer disposed on the thin film transistor structure layer; wherein the light-emitting device layer comprises an electron function layer, and a cathode disposed on a side of the electron function layer away from the thin film transistor structure layer; and
a support member disposed on the insulating layer and at junction between the buffer area and the cathode overlap area;
wherein in the buffer area, the light-emitting device layer is provided with at least one channel extending through the support member to the cathode overlap area, and the first opening is disposed in an extension direction of the channel; and
in the non-display area of an orthographic projection of the display panel, a boundary of the cathode exceeds a boundary of the electron function layer, the electron function layer covers at least the display area and the buffer area, and the cathode covers the display area and the buffer area and is connected to the wiring at the first opening through the channel.

2. The display panel of claim 1, wherein the light-emitting device layer comprises a flat layer covering the insulating layer and a pixel definition layer covering the flat layer, and the electron function layer covers the pixel definition layer; and
wherein a bottom surface height of the channel is lower than a surface of the pixel definition layer away from the thin film transistor structure layer and in the display area, with a reference surface made to a surface of the insulating layer close to the flat layer, and a bottom surface of the channel is higher than or equal to the reference surface.

3. The display panel of claim 2, wherein the channel includes at least one first hollow and a plurality of second hollows, one of the at least one first hollow communicates with at least one of the plurality of second hollows, the at least one first hollow and the plurality of second hollows extend through the flat layer and the pixel definition layer, the at least one first hollow is disposed in the buffer area, and the plurality of second hollows extends through the support member; and
wherein in the orthographic projection of the display panel, an extension direction of the plurality of second hollows intersects an extension direction of the wiring.

4. The display panel of claim 3, wherein at least one first opening is provided, and in the orthographic projection of the display panel, one of the at least one first opening is at least correspondingly provided in the extension direction of one of the plurality of second hollows.

5. The display panel of claim 4, wherein one first opening is provided, and in the orthographic projection of the display panel, the one first opening is arranged to extend along the extension direction of the wiring, and the one first opening is correspondingly arranged along the extension direction of the plurality of second hollows.

6. The display panel of claim 4, wherein in the orthographic projection of the display panel, the at least one first opening is provided at intervals along the extension direction of the wiring, and one of the at least one first opening is correspondingly provided in the extension direction of one of the plurality of second hollows.

7. The display panel of claim 6, wherein a plurality of support members is provided; in the orthographic projection of the display panel, the plurality of support members is arranged at intervals along the extension direction of the wiring; and each of the plurality of support members is disposed between two adjacent first openings in an extension direction parallel to the extension direction of the plurality of second hollows; and
wherein the cathode includes a plurality of overlapping portions in the cathode overlap area, each of the plurality of overlapping portions is provided in each of the at least one first opening and is connected to the wiring, and the plurality of overlapping portions is arranged at intervals along the extension direction of the wiring.

8. The display panel of claim 7, wherein in the orthographic projection of the display panel, each of the plurality of support members support member is disposed on side areas of each of the at least one first opening along the extension direction of the plurality of second hollows.

9. The display panel of claim 7, wherein a width of each of the plurality of second hollow ranges from 10 microns to 500 microns.

10. The display panel of claim 2, wherein at least one of the flat layer and the pixel definition layer is disposed in a same layer as at least a portion of the support member and has same material as the portion of the support member.

11. The display panel of claim 10, wherein the support member comprises a first portion, a second portion, and a third portion stacked on the insulating layer in sequence; the first portion is provided in a same layer as the flat layer and has same material as the flat layer; and the second portion is provided in a same layer as the pixel definition layer and has same material as the pixel definition layer.

12. The display panel of claim 2, wherein a width of the support member is greater than or equal to 10 microns.

13. The display panel of claim 1, wherein a thickness of the support member is greater than or equal to 4 microns.

14. The display panel of claim 1, wherein the electron function layer is connected to a portion of the wiring at the first opening through the channel, and the cathode covers the electron function layer in the first opening and is connected to an exposed portion of the wiring.

15. The display panel of claim 2, wherein the electron function layer comprises at least one of an electron transport layer and an electron injection layer; and the light-emitting device layer further comprises an anode, a light-emitting layer, and a hole function layer; wherein the anode is disposed on the flat layer, the pixel definition layer is provided with a second opening, and the second opening exposes the anode; wherein the hole function layer and the light-emitting layer are disposed on the anode in sequence and in the second opening, and the electron function layer is disposed on the light-emitting layer.

16. A preparation method of display panel, wherein the display panel comprises a display area and a non-display area located on at least one side of the display area; the non-display area comprises a buffer area and a cathode overlap area on a side of the buffer area away from the display area; and the preparation method of display panel comprises:
forming a support member on a thin film transistor structure layer including a wiring and an insulating layer covering the wiring; wherein a first opening is provided on the insulating layer in the cathode overlap area, the first opening exposes the wiring, the support member is provided on the insulating layer at a junction between the buffer area and the cathode overlap area, at least one channel is provided on the support member, the channel communicates with the buffer area and the cathode overlap area, and the first opening is disposed in an extension direction of the channel;
providing one mask on the support member, wherein an opening area of the mask is disposed corresponding to the display area and the buffer area, and a shielding area of the mask is disposed corresponding to the cathode overlap area; and
forming an electron function layer and a cathode on the thin film transistor structure layer in sequence with the mask, a boundary of the cathode exceeds a boundary of the electron function layer, the electron function layer covers at least the display area and the buffer area, and the cathode covers the display area and the buffer area and is connected to the wiring at the first opening through the channel.
